(19) United States
(12) Patent Application Publication
(10) Pub. No.: US 2025/0107314 A1
(43) Pub. Date: Mar. 27, 2025

(54) DISPLAY DEVICE AND METHOD FOR MANUFACTURING THE SAME

(71) Applicant: Samsung Display Co., LTD., Yongin-si (KR)

(72) Inventor: Dongjin Kang, Yongin-si (KR)

(21) Appl. No.: 18/677,106

(22) Filed: May 29, 2024

(30) Foreign Application Priority Data
Sep. 27, 2023 (KR) 10-2023-0130466

(51) Int. Cl. H10K 50/115; H10K 50/15; H10K 50/16; H10K 59/12; H10K 59/35

(52) U.S. Cl. CPC H10K 50/115; H10K 50/15; H10K 50/16; H10K 59/1201; H10K 59/35

(57) ABSTRACT

A display device includes a first light-emitting diode and a second light-emitting diode, wherein the first light-emitting diode includes a first lower electrode, a first inorganic functional layer, a quantum dot emission layer, a second inorganic functional layer, and a first upper electrode, wherein the second light-emitting diode includes a second lower electrode, a first organic functional layer, an organic emission layer, a second organic functional layer, and a second upper electrode, wherein a level of an upper surface of the first inorganic functional layer is higher in an edge portion of the first inorganic functional layer than in a central portion of the first inorganic functional layer, and a level of an upper surface of the first organic functional layer is equal in a central portion and an edge portion of the first organic functional layer.

### CROSS-REFERENCE TO RELATED APPLICATION

The present application claims priority to and the benefit of Korean Patent Application No. 10-2023-0130466, filed on Sep. 27, 2023, in the Korean Intellectual Property Office, the content of which in its entirety is herein incorporated by reference.

### BACKGROUND

### 1. Field

Aspects of one or more embodiments relate to a display device and a method of manufacturing the same.

### 2. Description of Related Art

In general, a display device includes light-emitting diodes and thin-film transistors on a substrate and operates by causing the light-emitting diodes to emit light. Light-emitting diodes convert electric energy into light energy. Examples of light-emitting diodes include organic light-emitting diodes of which an emission material is an organic material and quantum dot light-emitting diodes of which an emission material is a quantum dot.

For example, each pixel of the display device may include a light-emitting diode wherein an interlayer including an emission layer is arranged between a lower electrode and an upper electrode. The display device generally controls the emission of light or light-emitting degree of each pixel through the thin-film transistor electrically connected to the lower electrode. Some layers included in the interlayer of the light-emitting diode may be commonly provided in a plurality of light-emitting diodes.

The above information disclosed in this Background section is only for enhancement of understanding of the background and therefore the information discussed in this Background section does not necessarily constitute prior art.

### SUMMARY

One or more embodiments include a display device including a light-emitting diode having high luminescence efficiency and a long lifespan. However, the one or more embodiments are only examples, and the scope of the disclosure is not limited thereto.

Additional aspects will be set forth in part in the description which follows and, in part, will be apparent from the description, or may be learned by practice of the presented embodiments of the disclosure.

According to one or more embodiments, a display device includes a first light-emitting diode and a second light-emitting diode each on a substrate, the first light-emitting diode and the second light-emitting diode emitting lights of different colors from each other, wherein the first light-emitting diode includes a first lower electrode, a first inorganic functional layer on the first lower electrode and including an inorganic material, a quantum dot emission layer on the first inorganic functional layer and including a quantum dot, a second inorganic functional layer on the quantum dot emission layer and including an inorganic material, and a first upper electrode on the second inorganic functional layer, wherein the second light-emitting diode includes a second lower electrode, a first organic functional layer on the second lower electrode and including an organic material, an organic emission layer on the first organic functional layer and including an organic material, a second organic functional layer on the organic emission layer and including an organic material, and a second upper electrode on the second organic functional layer, wherein a level of an upper surface of the first inorganic functional layer is higher in an edge portion of the first inorganic functional layer than in a central portion of the first inorganic functional layer, and a level of an upper surface of the first organic functional layer is same in a central portion and an edge portion of the first organic functional layer.

According to one or more embodiments, a level of an upper surface of the quantum dot emission layer may be higher in an edge portion of the quantum dot emission layer than in a central portion of the quantum dot emission layer, and a level of an upper surface of the organic emission layer may be the same in a central portion and an edge portion of the organic emission layer.

According to one or more embodiments, a level of an upper surface of the second inorganic functional layer may be the same in a central portion and an edge portion of the second inorganic functional layer, and a level of an upper surface of the second organic functional layer may be the same in a central portion and an edge portion of the second organic functional layer.

According to one or more embodiments, the first inorganic functional layer may include at least one of molybdenum oxide, vanadium oxide, hydrogen molybdenum bronze, or hydrogen vanadium bronze.

According to one or more embodiments, the second inorganic functional layer may include at least one of titanium oxide, zinc oxide, zinc magnesium oxide, or tin oxide.

According to one or more embodiments, the first inorganic functional layer may include at least one of titanium oxide, zinc oxide, zinc magnesium oxide, or tin oxide.

According to one or more embodiments, the second inorganic functional layer may include at least one of molybdenum oxide, vanadium oxide, hydrogen molybdenum bronze, or hydrogen vanadium bronze.

According to one or more embodiments, the pixel device may further include a pixel defining layer on the substrate, covering an edge of each of the first lower electrode and the second lower electrode, and including a first opening exposing a central portion of the first lower electrode and a second opening exposing a central portion of the second lower electrode.

According to one or more embodiments, the first inorganic functional layer, the quantum dot emission layer, and the second inorganic functional layer may be arranged in the first opening of the pixel defining layer, and the first organic functional layer, the organic emission layer, and the second organic functional layer may be arranged in the second opening of the pixel defining layer.

According to one or more embodiments, the first upper electrode and the second upper electrode may be integrally provided.

According to one or more embodiments, a method of manufacturing a display device includes forming a first lower electrode and a second lower electrode on a substrate, performing an inkjet printing process on the first lower electrode to form a first inorganic functional layer including an inorganic material, performing an inkjet printing process on the first functional layer to form a quantum dot emission layer including a quantum dot, performing a vapor deposition process on the quantum dot emission layer to form a second inorganic functional layer, forming a first organic functional layer including an organic material on the second lower electrode, forming an organic emission layer on the first organic functional layer, forming a second organic functional layer including an organic material on the organic emission layer, and forming an upper electrode on the second inorganic functional layer and the second organic functional layer.

According to one or more embodiments, the first organic functional layer may be formed by the vapor deposition process.

According to one or more embodiments, the forming of the first organic functional layer may be performed after the forming of the second inorganic functional layer.

According to one or more embodiments, the organic emission layer and the second organic functional layer may be formed by the vapor deposition process.

According to one or more embodiments, the first inorganic functional layer may include at least one of molybdenum oxide, vanadium oxide, hydrogen molybdenum bronze, or hydrogen vanadium bronze.

According to one or more embodiments, the second inorganic functional layer may include at least one of titanium oxide, zinc oxide, zinc magnesium oxide, or tin oxide.

According to one or more embodiments, the first inorganic functional layer may include at least one of titanium oxide, zinc oxide, zinc magnesium oxide, or tin oxide.

According to one or more embodiments, the second inorganic functional layer may include at least one of molybdenum oxide, vanadium oxide, hydrogen molybdenum bronze, or hydrogen vanadium bronze.

According to one or more embodiments, the method of manufacturing the display device may further include forming a pixel defining layer on the substrate, covering an edge of each of the first lower electrode and the second lower electrode, and including a first opening exposing a central portion of the first lower electrode and a second opening exposing a central portion of the second lower electrode.

According to one or more embodiments, the first inorganic functional layer, the quantum dot emission layer, and the second inorganic functional layer may be arranged in the first opening of the pixel defining layer, and the first organic functional layer, the organic emission layer, and the second organic functional layer may be arranged in the second opening of the pixel defining layer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display device according to an embodiment;

FIG. 2 is an equivalent circuit diagram of a pixel circuit electrically connected to a light-emitting diode included in a pixel of the display device of FIG. 1;

FIGS. 3A and 3B are schematic cross-sectional views of a display device according to an embodiment;

FIG. 4 is a schematic plan view of the display device according to an embodiment;

FIG. 5 is a schematic cross-sectional view of the display device taken along the line I-I′ of FIG. 4; and

FIGS. 6 to 13 are each a schematic cross-sectional view of a manufacturing process of the display device according to some embodiments.

### DETAILED DESCRIPTION

Reference will now be made in more detail to aspects of some embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b, or c” indicates only a, only b, only c, both a and b, both a and c, both b and c, all of a, b, and c, or any combination of a, b, and/or c.

Because the disclosure may have diverse modified embodiments, aspects of some example embodiments are illustrated in the drawings and are described in the detailed description. An effect and a characteristic of the disclosure, and a method of accomplishing these will be apparent when referring to embodiments described with reference to the drawings. The disclosure may, however, be embodied in many different forms and should not be construed as limited to the embodiments set forth herein.

Hereinafter, embodiments will be described in detail with reference to the accompanying drawings, wherein the same or corresponding elements are denoted by the same reference numerals throughout and a repeated description thereof is omitted.

In the embodiments below, the terms “first” and “second” are not used in a limited sense and are used to distinguish one component from another component. As used herein, the singular expressions “a,” “an,” and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components. It will be understood that when a layer, region, or element is referred to as being formed “on” another layer, area, or element, it can be directly or indirectly formed on the other layer, region, or element. That is, for example, intervening layers, regions, or elements may be present.

In the drawings, for convenience of description, sizes of components may be exaggerated or reduced. In other words, because sizes and thicknesses of elements in the drawings are arbitrarily illustrated for convenience of description, the following embodiments are not limited thereto.

When a certain embodiment may be implemented differently, a specific process order may be performed differently from the described order. For example, two consecutively described processes may be performed substantially at the same time or performed in an order opposite to the described order.

In the embodiments hereinafter, it will be understood that when an element, an area, or a layer is referred to as being connected to another element, area, or layer, it can be directly and/or indirectly connected to the other element, area, or layer. For example, it will be understood in this specification that when an element, an area, or a layer is referred to as being in contact with or being electrically connected to another element, area, or layer, it can be directly and/or indirectly in contact with or electrically connected to the other element, area, or layer.

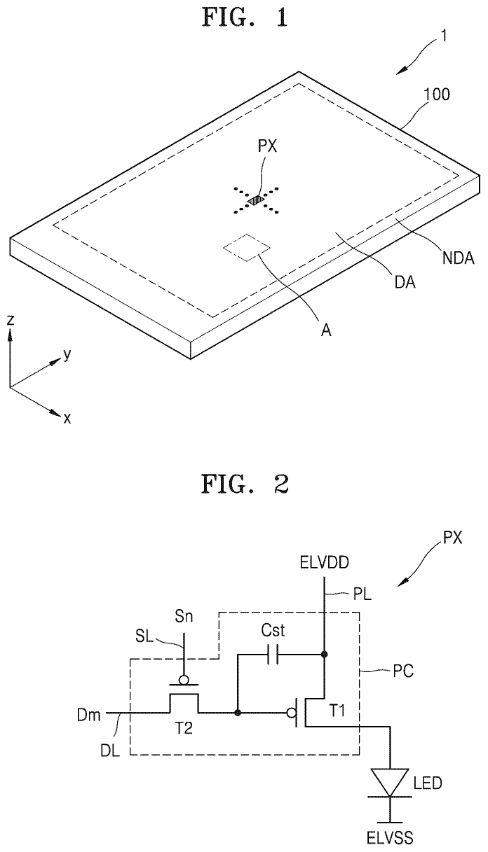

FIG. 1 is a schematic perspective view of a display device according to some embodiments.

Referring to FIG. 1, a display device 1 may include a display area DA and a non-display area NDA on a substrate 100.

Images may be implemented on the display area DA. In the display area DA, a plurality of pixels PX arranged two-dimensionally on a plane. The display device 1 may display images by using light emitted from the plurality of pixels PX.

The non-display area NDA does not display images and does not include the pixels PX. The entire display area DA may be surrounded by the non-display area NDA. In the non-display area NDA may include a driver or a voltage wiring to provide electrical signals or power to the pixels PX. A pad portion wherein an electronic element, a printed circuit board, etc. are electrically connected thereto may be arranged in the non-display area NDA.

The display area DA may have a polygonal shape. For example, the display area DA may have a rectangular shape of which the horizontal length is greater than the vertical length as shown in FIG. 1. Alternatively, the display area DA may have a square shape. Alternatively, the display area DA may have various shapes such as an ellipse or a circle.

FIG. 2 is an equivalent circuit diagram of a pixel circuit electrically connected to a light-emitting diode included in a pixel of the display device 1 of FIG. 1.

Referring to FIG. 2, the pixel PX may include a pixel circuit PC, a display element connected to the pixel circuit PC, for example, a light-emitting diode LED. The pixel circuit PC may include a first thin-film transistor T1, a second thin-film transistor T2, and a storage capacitor Cst. Each pixel PX may emit light, such as red, green, or blue light, or emit red, green, blue, or white light, through the light-emitting diode LED.

The second thin-film transistor T2 may be a switching thin-film transistor, may be connected to a scan line SL and a data line DL, and may be configured to transmit, to the first thin-film transistor T1, a data voltage or a data signal Dm input from the data line DL according to a switching voltage or a switching signal Sn input from the scan line SL. The storage capacitor Cst may be connected to the second thin-film transistor T2 and a driving voltage line PL and may be configured to store a voltage corresponding to a difference between a voltage received from the second thin-film transistor T2 and a first power voltage ELVDD supplied to the driving voltage line PL.

The first thin-film transistor T1 may be a driving thin-film transistor, may be connected to the driving voltage line PL and the storage capacitor Cst, and may be configured to control a driving current flowing from the driving voltage line PL through the light-emitting diode LED, according to a value of the voltage stored in the storage capacitor Cst. The light-emitting diode LED may emit light having a certain brightness according to the driving current. An upper electrode (e.g., a cathode) of the light-emitting diode LED may receive a second power voltage ELVSS.

FIG. 2 illustrates that the pixel circuit PC includes two thin-film transistors and one storage capacitor, but the number of thin-film transistors and storage capacitors may vary according to the design of the pixel circuit PC according to some embodiments.

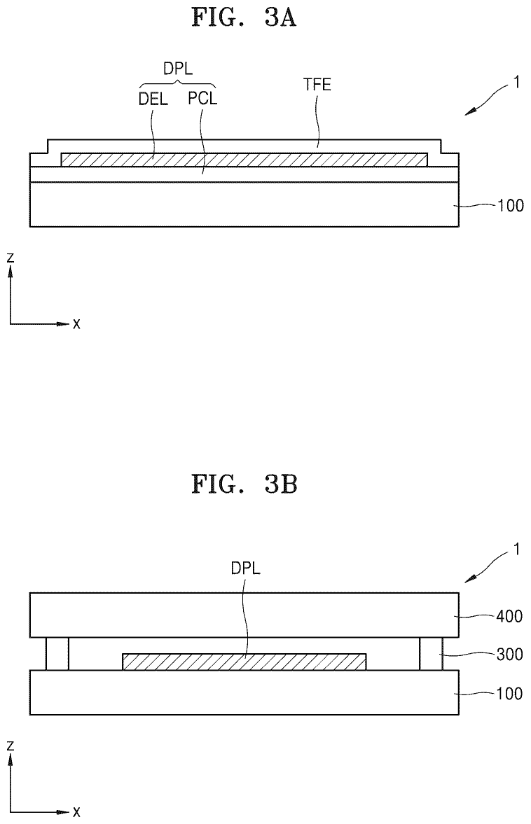

FIG. 3A is a schematic cross-sectional view of the display device 1 according to some embodiments and FIG. 3B is a schematic cross-sectional view of the display device 1 according to some embodiments.

Referring to FIG. 3A, a display layer DPL and a thin-film encapsulation layer TFE may be included on the substrate 100 of the display device 1. The display layer DPL may include a pixel circuit layer PCL including a pixel circuit and insulating layers, and a display element layer DEL located on the pixel circuit layer PCL and including a plurality of display elements.

The substrate 100 may include glass, metal, or polymer resin. The polymer resin may include polyethersulfone, polyacrylate, polyetherimide, polyethylene naphthalate, polyethylene terephthalate, polyphenylene sulfide, polyarylate, polyimide, polycarbonate, cellulose acetate propionate, or a mixture thereof. However, the substrate 100 may have a multi-layer structure including two layers and a barrier layer therebetween, each of the two layers may include polymer resin, and the barrier layer may include an inorganic material, such as silicon oxide (SiOₓ), silicon nitride (SiNₓ), and silicon oxynitride (SiON), and various modifications may be made.

The display element layer DEL may include light-emitting elements, for example, organic light-emitting elements, quantum dot light-emitting elements, etc. The pixel circuit layer PCL may include the pixel circuit and the insulating layers connected to the light-emitting diode. For example, the pixel circuit layer PCL may include a plurality of transistors, a plurality of storage capacitors, and insulation layers between the transistors and the storage capacitors.

The display elements may be covered with an encapsulation member such as the thin-film encapsulation layer TFE. The thin-film encapsulation layer TFE may include at least one inorganic encapsulation layer and at least one organic encapsulation layer to cover the display element layer DEL. The inorganic encapsulation layer may include inorganic insulating materials such as aluminum oxide (Al₂O₃), titanium oxide (TiO₂), tantalum oxide (Ta₂O₅), hafnium oxide (HfO₂), zinc oxide (ZnO), silicon oxide (SiOₓ), silicon nitride (SiNₓ), or silicon oxynitride (SiON). The organic encapsulation layer may include a polymer-based material. Examples of the polymer-based material may include an acrylic resin, an epoxy resin, polyimide, and polyethylene. According to some embodiments, the organic encapsulation layer may include acrylate.

Referring to FIG. 3B, the display layer DPL and a sealing substrate 400 may be located on the substrate 100 of the display device 1. A sealing member 300 may be arranged between the substrate 100 and the sealing substrate 400. The sealing substrate 400 may be a transparent member. The substrate 100 and the sealing substrate 400 may be coupled to each other with the sealing member 300, and the inner space between the substrate 100 and the sealing substrate 400 may be sealed. In this case, an absorber or a filler may be arranged in the inner space. The sealing member 300 may be a sealant and, according to some embodiments, the sealing member 300 may include a material that may be hardened by a laser. For example, the sealing member 300 may be a frit. For example, the sealing member 300 may include an organic sealant such as urethane resin, epoxy resin, or acrylic resin, or an inorganic sealant such as silicon. Urethane acrylate, for example, may be used as a urethane resin. As an acrylic resin, for example, butyl acrylate, ethylhexyl acrylate, etc. may be used. The sealing member 300 may include a material hardened by heat.

According to some embodiments, the display element layer DEL may be covered by the sealing substrate 400 and the sealing member 300 of FIG. 3B together with the thin-film encapsulation layer TFE of FIG. 3A.

A touch electrode layer may be located on the thin-film encapsulation layer TFE and/or the sealing substrate 400, and an optical functional layer may be located on the touch electrode layer. The touch electrode layer may obtain coordinate information based on an external input, for example, a touch event. The optical functional layer may reduce the reflectivity of the light (external light) incident toward the display device 1 from the outside. Or the optical functional layer may improve the color purity of light emitted from the display device 1. According to some embodiments, the optical functional layer may include a retarder and/or a polarizer. The retarder may be a film type or liquid crystal coating type, and may include a λ/2 retarder and/or a λ/4 retarder. The polarizer may also be a film type or a liquid crystal coating type. The film type may include an elongated synthetic resin film, and the liquid crystal coating type may include liquid crystals arranged in a certain arrangement. The retarder and the polarizer may further include a protection film.

According to some embodiments, the optical functional layer may include a black matrix and color filters. The color filters may be arranged in consideration of the colors of light emitted from each of the pixels of the display device 1. Each color filter may include red, green, or blue pigments or dyes. Alternatively, each color filter may further include quantum dots in addition to the above-described pigments or dyes. Alternatively, some of the color filters may not contain the pigments or dyes described above, and may include scattering particles such as titanium oxide.

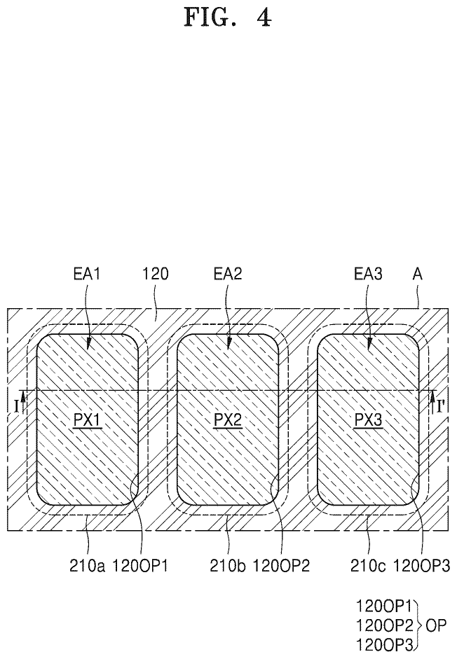

FIG. 4 is a schematic plan view of the display device according to some embodiments.

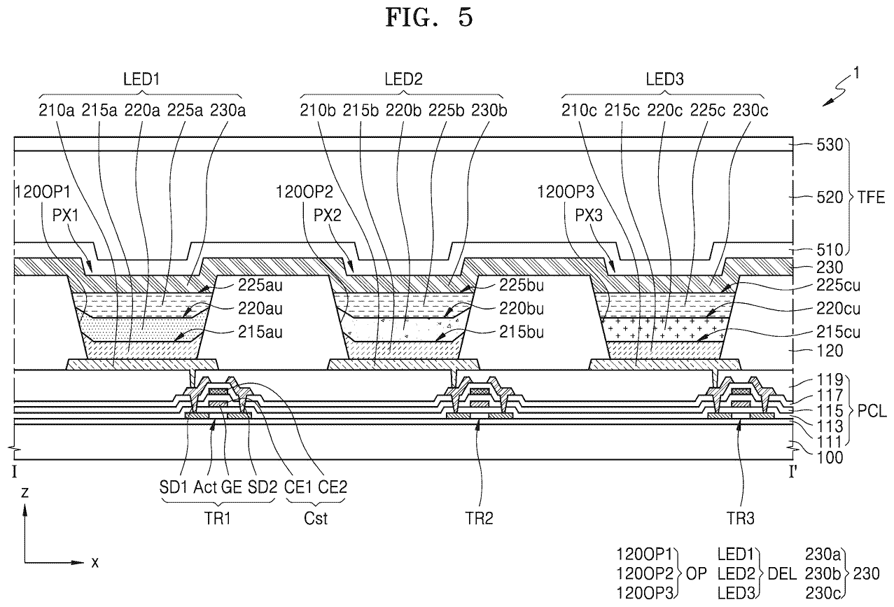

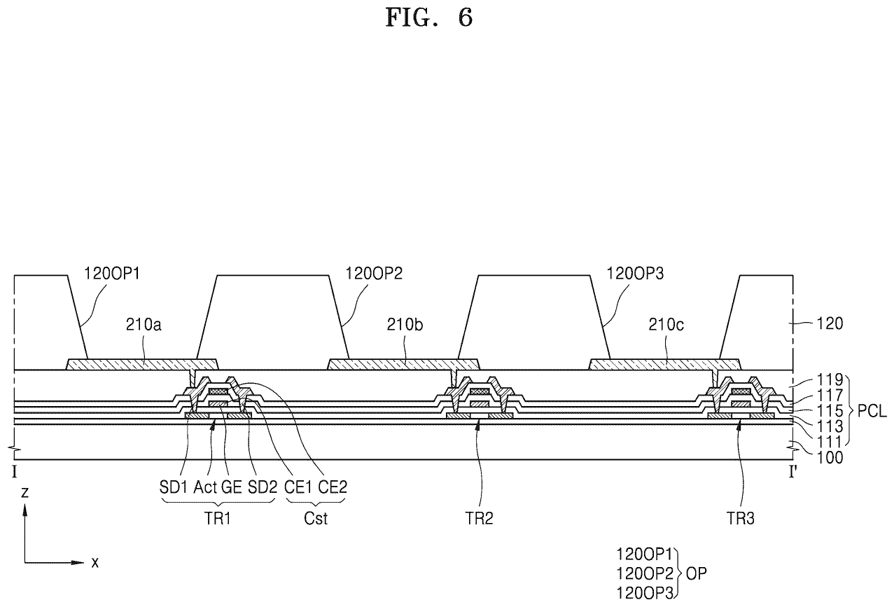

Referring to FIG. 4, the display device 1 may include a plurality of pixels PX (FIG. 1). The plurality of pixels PX (FIG. 1) may include a first pixel PX1, a second pixel PX2, and a third pixel PX3. The first pixel PX1 may include a first light-emitting diode LED1 (FIG. 5), the second pixel PX2 may include a second light-emitting diode LED2 (FIG. 5), and the third pixel PX3 may include a third light-emitting diode LED3. The first pixel PX1, the second pixel PX2, and the third pixel PX3 may emit different colors of light. For example, the first pixel PX1 may emit red light, the second pixel PX2 may emit green light, and the third pixel PX3 may emit blue light, but such embodiments are only examples and embodiments according to the present disclosure are not limited thereto. For example, the first pixel PX1 may emit green light, the second pixel PX2 may emits blue light, and the third pixel PX3 may emit red light. For example, the first pixel PX1 may emit red light, the second pixel PX2 may emit blue light, and the third pixel PX3 may emit green light. Red light belongs to a wavelength band in a range of 580 nanometers (nm) (or about 580 nm) to 780 nm (or about 780 nm), blue light belongs to a wavelength band of 380 nm (or about 380 nm) to 495 nm (or about 495 nm), and green light belongs to a wavelength band in a range of 495 nm (or about 495 nm) to 580 nm (or about 580 nm).

Each light-emitting diode may include a lower electrode, an upper electrode, and an interlayer located therebetween. Accordingly, the first pixel PX1 may include a first lower electrode 210a of the first light-emitting diode LED1 (FIG. 5), the second pixel PX2 may include a second lower electrode 210b of the second light-emitting diode (FIG. 5), and the third pixel PX3 may include a third lower electrode 210c of the third light-emitting diode LED3 (FIG. 5). The first lower electrode 210a, the second lower electrode 210b, and the third lower electrode 210c may be spaced apart from each other on the substrate 100 (FIG. 5). Herein, “from a plan view” refers to a plane viewed from a direction perpendicular or normal to the substrate 100. In other words, “A and B being apart from each other from a plan view” refers to “A and B being apart from each other when viewed from a direction perpendicular to the substrate 100.”

A pixel defining layer 120 may be located on the first lower electrode 210a, the second lower electrode 210b, and the third lower electrode 210c and may cover each of the first lower electrode 210a, the second lower electrode 210b, and the third lower electrode 210c. The pixel defining layer 120 may include a first opening 120OP1 exposing a central portion of the first lower electrode 210a, a second opening 12OP2 exposing a central portion of the second lower electrode 210b, and a third opening 120OP3 exposing a central portion of the third lower electrode 210c.

According to some embodiments, the emission layers that emit light may be respectively located in the first opening 120OP1, the second opening 120OP2, and the third opening 120OP3. The upper electrode may be located on the emission layers. As described above, a stacked structure of the lower electrode, the emission layer, and the upper electrode may form the light-emitting diode. One opening of the pixel defining layer 120 corresponds to one light-emitting diode and may define one emission area.

For example, an emission layer emitting red light is arranged in the first opening 120OP1 such that the first opening 120OP1 may define a first emission area EA1. Similarly, an emission layer emitting green light is arranged in the second opening 120OP2 such that the second opening 120OP2 may define a second emission area EA2. An emission layer emitting blue light is arranged in the third opening 120OP3 such that the third opening 120OP3 may define a third emission area EA3. Accordingly, the size of the area of the first opening 120OP1 may be the same as the size of the area of the first emission area EA1. The size of the area of the second opening 120OP2 may be the same as the size of the area of the second emission area EA2. The size of the area of the third opening 120OP3 may be the same as the size of the area of the third emission area EA3.

Each of the first opening 120OP1, the second opening 120OP2, and the third opening 120OP3 may have a polygonal shape when viewed from a direction (a z-axis direction) perpendicular to the substrate 100 (FIG. 5). In other words, the first emission area EA1, the second emission area EA2, and the third emission area EA3 may each have a polygonal shape when viewed from the direction (the z-axis direction) perpendicular to the substrate 100. FIG. 4 illustrates that the first emission area EA1, the second emission area EA2, and the third emission area EA3 each have a rectangular shape, particularly a rectangular shape having round edges, when viewed from the direction (the z-axis direction) perpendicular to the substrate 100, but the disclosure is not limited thereto. For example, the first emission area EA1, the second emission area EA2, and the third emission area EA3 may each have a circular or elliptical shape when viewed from the direction (the z-axis direction) perpendicular to the substrate 100.

FIG. 4 illustrates that the first pixel PX1, the second pixel PX2, and the third pixel PX3 are arranged in a stripe structure, but embodiments are not limited thereto. For example, the first pixel PX1, the second pixel PX2, and the third pixel PX3 may be arranged in various pixel array structures such as Pentile™ structure, a mosaic structure, a delta structure, or the like.

FIG. 5 is a schematic cross-sectional view of the display device taken along the line I-I′ of FIG. 4.

Referring to FIG. 5, the display device 1 may include the substrate 100, the pixel circuit layer PCL on the substrate 100, and the display element layer DEL on the pixel circuit layer PCL. According to some embodiments, the display device 1 may further include the thin-film encapsulation layer TFE on the display element layer DEL.

The pixel circuit layer PCL may include a first transistor TR1, a second transistor T2, and a third transistor TR3, a buffer layer 111 arranged below and/or above components of the transistor, a first gate insulating layer 113, a second gate insulating layer 115, an interlayer insulating layer 117, and a planarization layer 119. Here, the first transistor TR1, the second transistor TR2, and the third transistor TR3 may each correspond to the first thin-film transistor T1 of FIG. 2. Because the structure of the second transistor TR2 and the third transistor TR3 is the same or similar to the structure of the first transistor TR1, redundant descriptions thereof are omitted.

The buffer layer 111 may include inorganic insulating materials such as SiNₓ, SiON, or SiO₂ and may have a single-layer or multi-layer structure including the inorganic insulating materials described above. The buffer layer 111 may planarize the upper surface of the substrate 100 and may prevent, reduce, or minimize instances of contaminants or impurities penetrating into a semiconductor layer Act from the substrate 100 or the like.

The first transistor TR1 may include the semiconductor layer Act, and the semiconductor layer Act may include polysilicon. Alternatively, the semiconductor layer Act may include amorphous silicon, an oxide semiconductor material, or an organic semiconductor material.

A gate electrode GE may overlap a portion of the semiconductor layer Act. The gate electrode GE may include a conductive material. For example, the gate electrode GE may include conductive materials such as molybdenum (Mo), aluminum (Al), or titanium (Ti), and may have a multilayer structure or a single layer structure including the above material.

The first gate insulating layer 113 between the semiconductor layer Act and the gate electrode GE may include an inorganic insulating material such as silicon oxide (SiOₓ), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnO), or the like.

The second gate insulating layer 115 may cover the gate electrode GE. The second gate insulating layer 115 may, similarly to the first gate insulating layer 113, include an inorganic insulating material such as and the second inorganic encapsulation layer 330 may include inorganic insulating materials such as SiOₓ, SiNₓ, SiON, Al₂O₃, TiO₂, Ta₂O₅, HfO₂, ZnO, or the like.

A second capacitor electrode CE2 of the storage capacitor Cst may be located on the second gate insulating layer 115. The second capacitor electrode CE2 may overlap the gate electrode GE therebelow. In this case, the gate electrode GE and the second capacitor electrode CE2 overlapping each other with the second gate insulating layer 115 therebetween may form the storage capacitor Cst. That is, the gate electrode GE may function as a first capacitor electrode CE1 of the storage capacitor Cst.

As described above, the storage capacitor Cst may overlap the first transistor TR1. According to some embodiments, the storage capacitor Cst may not overlap the first transistor TR1.

The second capacitor electrode CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may have a single-layer or multi-layer structure including the materials described above.

The interlayer insulating layer 117 may cover the second capacitor electrode CE2. The interlayer insulating layer 117 may include an inorganic insulating material such as SiO₂, SiNₓ, SiON, Al₂O₃, TiO₂, Ta₂O₅, HfO₂, or ZnO. The interlayer insulating layer 117 may have single-layer of multi-layer structure including the above inorganic insulating materials.

The drain electrode SD1 and the source electrode SD2 may each be located on the interlayer insulating layer 117. The drain electrode SD1 and the source electrode SD2 may each be electrically connected to the semiconductor layer Act through a contact hole included in the first gate insulating layer 113, the second gate insulating layer 115, and the interlayer insulating layer 117. The drain electrode SD1 and the source electrode SD2 may include materials with great conductivity. The drain electrode SD1 and the source electrode SD2 may include conductive materials including Mo, Al, Cu, Ti, etc. and have a single-layer or multi-layer structure including the materials described above. For example, the drain electrode SD1 and the source electrode SD2 may have a multi-layer structure of Ti/Al/Ti. According to some embodiments, one of the drain electrode SD1 and the source electrode SD2 may be omitted and a portion of the semiconductor layer Act may be conductive and replace the omitted component.

The planarization layer 119 may cover the first transistor TR1 and include a contact hole exposing a portion of the first transistor TR1. The planarization layer 119 may include an organic insulating layer. The planarization layer 119 may include an organic insulating material, such as a general-purpose polymer, such as polymethylmethacrylate (PMMA) or polystyrene (PS), polymer derivatives having a phenol-based group, acryl-based polymers, imide-based polymers, arylether-based polymers, amide-based polymers, fluorine-based polymers, p-xylene-based polymers, vinyl alcohol-based polymers, and a blend thereof.

The display element layer DEL may be located on the pixel circuit layer PCL. The display element layer DEL may include the first light-emitting diode LED1, the second light-emitting diode LED2, and the third light-emitting diode LED3. The display element layer DEL may include a quantum dot light-emitting diode and an organic light-emitting diode including an emission layer. For example, the first light-emitting diode LED1 and the second light-emitting diode LED2 may be quantum dot light-emitting diodes, and the third light-emitting diode LED3 may be an organic light-emitting diode. However, embodiments according to the present disclosure are not limited thereto, and a combination of the quantum dot light-emitting diode and the organic light-emitting diode may be variously modified. For example, the first light-emitting diode LED1 may be a quantum dot light-emitting diode and the second light-emitting diode LED2 and the third light-emitting diode LED3 may be organic light-emitting diodes. The quantum dot light-emitting diode may include an emission layer including a quantum dot and the organic light-emitting diode may not include a quantum dot and include an emission layer including an organic material. Hereinafter, for convenience of explanation, descriptions are based on the assumption that the first light-emitting diode LED1 and the second light-emitting diode LED2 are each a quantum dot light-emitting diode and the third light-emitting diode LED3 is an organic light-emitting diode.

Each of the first light-emitting diode LED1, the second light-emitting diode LED2, and the third light-emitting diode LED3 may include a lower electrode, an interlayer, and an upper electrode. In addition, each of the first light-emitting diode LED1, the second light-emitting diode LED2, and the third light-emitting diode LED3 may further include a first functional layer between the lower electrode and the interlayer and a second functional layer between the upper electrode and the interlayer.

The first light-emitting diode LED1 may include the first lower electrode 210a, a first interlayer 220a on the first lower electrode 210a, and a first upper electrode 230a on the first interlayer 220a. The first light-emitting diode LED1 may further include a first-1 functional layer 215a between the first lower electrode 210a and the first interlayer 220a, and a second-1 functional layer 225a between the first upper electrode 230a and the first interlayer 220a.

The second light-emitting diode LED2 may include the second lower electrode 210b, a second interlayer 220b on the second lower electrode 210b, and a second upper electrode 230b on the second interlayer 220b. The second light-emitting diode LED2 may further include a first-2 functional layer 215b between the second lower electrode 210b and the second interlayer 220b, and a second-2 functional layer 225b between the second upper electrode 230b and the second interlayer 220b.

The third light-emitting diode LED3 may include the third lower electrode 210c, a third interlayer 220c, and a third upper electrode 230c. The third light-emitting diode LED3 may further include a first-3 functional layer 215c between the third lower electrode 210c and the third interlayer 220c, and a second-3 functional layer 225c between the third upper electrode 230c and the third interlayer 220c.

The first lower electrode 210a, the second lower electrode 210b, and the third lower electrode 210c may be located on the pixel circuit layer PCL. The first lower electrode 210a, the second lower electrode 210b, and the third lower electrode 210c may be located on the planarization layer 119. The first lower electrode 210a may be electrically connected to the drain electrode SD1 or the source electrode SD2 of the first transistor TR1 through the contact hole penetrating the planarization layer 119. The first lower electrode 210a, the second lower electrode 210b, and the third lower electrode 210c may be spaced apart from each other in a first direction (e.g., an x direction).

The first lower electrode 210a, the second lower electrode 210b, and the third lower electrode 210c may be (semi-) transmissive electrodes or reflective electrodes. The first lower electrode 210a, the second lower electrode 210b, and the third lower electrode 210c may each include a reflective layer including Ag, Mg, Al, Pt, Pd, Au, Ni, Nd, Ir, Cr, and compounds thereof and a transparent or semi-transparent electrode layer formed on the reflective layer. The transparent or semi-transparent electrode layer may include at least one of indium tin oxide (ITO), indium zinc oxide (IZO), zinc oxide (ZnO), indium oxide (In₂O₃), indium gallium oxide (IGO), or aluminum zinc oxide (AZO). According to some embodiments, each of the first lower electrode 210a, the second lower electrode 210b, and the third lower electrode 210c may include ITO/Ag/ITO.

The display device 1 may further include a pixel defining layer 120 located on the pixel circuit layer PCL. The pixel defining layer 120 may cover edges of the first lower electrode 210a, the second lower electrode 210b, and the third lower electrode 210c. The pixel defining layer 120 may be in direct contact with upper surfaces and side surfaces of the first lower electrode 210a, the second lower electrode 210b, and the third lower electrode 210c.

According to some embodiments, the pixel defining layer 120 may include an organic material such as acryl, benzocyclobutene (BCB), or hexamethyldisiloxane (HMDSO). According to some embodiments, the pixel defining layer 120 may include a photoresist, that is, a photosensitive resin. For example, a negative type photoresist wherein a cross-linking response is caused during light exposure is included.

The pixel defining layer 120 may define the first opening 120OP1 exposing the central portion of the first lower electrode 210a, the second opening 12OP2 exposing the central portion of the second lower electrode 210b, and the third opening 120OP3 exposing the central portion of the third lower electrode 210c. By increasing the distance between the first to third lower electrodes 210a, 210b, 210c and the upper electrode 230, thereby preventing or reducing instances of an arc being generated in edges of the first to third lower electrodes 210a, 210b, and 210c.

The first emission layer 220a may be arranged in the first opening 120OP1 of the pixel defining layer 120. The first emission layer 220a may be located on the first-1 functional layer 215a described in more detail below. The second emission layer 220b may be arranged in the second opening 120OP2 of the pixel defining layer 120. The third emission layer 220c may be located on a first-2 functional layer 215b described below. The third emission layer 220c may be arranged in the third opening 120OP3 of the pixel defining layer 120. The third emission layer 220c may be located on the first-3 functional layer 215c described below.

The level of an upper surface 220au of the first emission layer 220a may be higher in the edge portion of the first emission layer 220a than in the central portion of the first emission layer 220a. Likewise, the level of an upper surface 220bu of the second emission layer 220b may be higher in the edge portion of the second emission layer 220b than in the central portion of the second emission layer 220b. In contrast, an upper surface 220cu of the third emission layer 220c may be substantially flat. Thus, the level of the upper surface 220cu of the third emission layer 220c may be substantially the same in the central portion of the third emission layer 220c and the edge portion of the third emission layer 220c.

The first emission layer 220a and the second emission layer 220b may be formed by the inkjet printing process and the third emission layer 220c may be formed by a vapor deposition process. For example, the vapor deposition process may include physical vapor deposition (PVD), chemical vapor deposition (CVD), sputtering, or thermal evaporation. The first emission layer 220a and the second emission layer 220b are formed in the same process and thus may have similar shapes. For example, as shown in FIG. 5, the level of each of the upper surface 220au of the first emission layer 220a and the upper surface 220bu of the second emission layer 220b may be lower in the central portions thereof than in the edge portions thereof, thereby forming a concave shape. In contrast, the third emission layer 220c is formed in a different process from that of the first emission layer 220a and the second emission layer 220b and thus may have a different shape from those of the first emission layer 220a and the second emission layer 220b. For example, as shown in FIG. 5, the upper surface 220cu of the third emission layer 220c may be flat (or substantially flat) unlike the upper surface 220au of the first emission layer 220a and the upper surface 220bu of the second emission layer 220b.

Herein, “the level of ‘A’ is higher than ‘B’ means that a distance between an upper end of A and an upper surface of the substrate 100 is greater than a distance between an upper end of B and an upper surface of the substrate 100. For example, the distance between the upper surface 220au of the first emission layer 220a and the upper surface of the substrate 100 may be greater in the central portion of the first emission layer 220a than in the edge portion of the first emission layer 220a.

Herein, the central portion of the emission layer and the functional layer may be the center of the opening of the pixel defining layer 120, and the edge portion of the emission layer and the functional layer may be arranged outside the central portion and adjacent to an inner wall of the pixel defining layer defining the opening of the pixel defining layer.

According to some embodiments, the first emission layer 220a and the second emission layer 220b may include an inorganic emission material. For example, the first emission layer 220a and the second emission layer 220b may include quantum dots. According to some embodiments, the first emission layer 220a and the second emission layer 220b including quantum dots may be referred to as a first quantum dot emission layer and the second quantum dot emission layer, respectively. The quantum dots included in the first emission layer 220a and the second emission layer 220b may act as dopants, and the emission layers may further include hosts and/or delayed fluorescent materials. The quantum dots refer to the crystal of the semiconductor compound. Quantum dots may emit light of various emission wavelength according to the size of the crystal. The quantum dots may emit light of various emission wavelengths by the control of the element ratio of the quantum dots. For example, the diameter of the quantum dot may be from about 1 nm to about 10 nm.

The quantum dots may be synthesized by a wet chemical process, a metal organic chemical vapor deposition (MOCVD) process, a molecular beam epitaxy (MBE) processes, or other similar processes. The wet chemical process is a method of growing quantum dot particle crystals after mixing organic solvents and precursor materials. When the crystal grows, because the organic solvent naturally acts as a dispersant coordinated on the surface of the quantum dot crystal and controls the growth of the crystal, the growth of the quantum dot particle may be controlled more easily and with lower costs than using vapor deposition methods such as MOCVD or MBE.

The quantum dot may include a Group II-VI semiconductor compound; a Group III-V semiconductor compound; a Group III-VI semiconductor compound; a Group I-III-VI semiconductor compound; a Group IV-VI semiconductor compound; a Group IV element or compound; or a combination thereof.

Examples of the Group II-VI semiconductor compound are binary compounds such as CdS, CdSe, CdTe, ZnS, ZnSe, ZnTe, ZnO, HgS, HgSe, HgTe, MgSe, and MgS; tertiary compounds such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, and MgZnS; quaternary compounds such as CdZnSeS, CdZnSeTe, CdZnSTe, CdHgSeS, CdHgSeTe, CdHgSTe, HgZnSeS, HgZnSeTe, and HgZnSTe; or a combination thereof.

Examples of the Group III-V semiconductor compound are binary compounds such as GaN, GaP, GaAs, GaSb, AlN, AlP, AlAs, AlSb, InN, InP, InAs, and InSb; tertiary compounds such as GaNP, GaNAs, GaNSb, GaPAs, GaPSb, AlNP, AlNAs, AlNSb, AlPAs, AlPSb, InGaP, InNP, InAIP, InNAs, InNSb, InPAs, and InPSb; quaternary compounds such as GaAINP, GaAINAs, GaAINSb, GaAIPAs, GaAIPSb, GalnNP, GalnNAs, GalnNSb, GalnPAs, GalnPSb, InAINP, InAINAs, InAINSb, InAIPAs, and InAIPSb; or a combination thereof. The Group III-V semiconductor compound may further include a Group II element. Examples of the Group III-V semiconductor compound further including the Group II element are InZnP, InGaZnP, InAIZnP, etc.

Examples of the Group III-VI semiconductor compound are binary compounds such as GaS, Ga2S3, GaSe, Ga2Se3, GaTe, InS, InSe, In2S3, In2Se3, and InTe; tertiary compounds such as InGaS3 and InGaSe3; or a combination thereof.

Examples of the Group I-III-VI compound are tertiary compounds such as AgInS, AgInS2, AgInSe2, AgGaS, AgGaS2, AgGaSe2, CuInS, CuInS2, CuInSe2, CuGaS2, CuGaSe2, CuGaO2, AgGaO2, and AgAlO2; quaternary compounds such as AgInGaS2, AgInGaSe2, and CuInGaS; or a combination thereof.

Examples of the Group IV-VI compound are binary compounds such as SnS, SnSe, SnTe, PbS, PbSe, and PbTe; tertiary compounds such as SnSeS, SnSeTe, SnSTe, PbSeS, PbSeTe, PbSTe, SnPbS, SnPbSe, and SnPbTe; quaternary compounds such as SnPbSSe, SnPbSeTe, and SnPbSTe; or a combination thereof.

The Group IV element or compound may include single elements such as Si and Ge; binary compounds such as SiC and SiGe; or a combination thereof.

The element included in a multi-element compound, such as the binary compound, the tertiary compound, and the quaternary compound may be present in a particle in a uniform concentration or in an uneven concentration. In other words, the formula represents the type of element included in the compound, and the element ratios of the compounds may be different. For example, AgInGaS2 may represent AgInxGa1-xS2 (x is a real number between 0 and 1).

The quantum dot may have a single structure or a core-shell double structure wherein each of the elements included in the quantum dot has a uniform concentration. For example, the material included in the core and the material included in the shell may be different from each other. The shell may cover at least a portion of the core.

The core may include Cd, Zn, Hg, Mg, Ga, Al, In, Sn, Pb, Se, Te, P, or Sb.

The shell of the quantum dot may act as a protective layer to prevent or reduce chemical denaturation of the core to maintain the semiconductor characteristics and/or may act as a charging layer to impart electrophoretic characteristics to the quantum dots. The shell may be a single layer or multiple layers. An interface between the core and the shell may have a concentration gradient wherein the concentration of the elements of the shell decreases toward the core.

Examples of the shell of the quantum dot are metal or non-metal oxides, semiconductor compounds, or combinations thereof. Examples of the metal or non-metal oxides are binary compounds such as SiO2, Al2O3, TiO2, ZnO, MnO, Mn2O3, Mn3O4, CuO, FeO, Fe2O3, Fe3O4, CoO, Co3O4, NiO, and the like, tertiary compounds such as MgAl2O4, CoFe2O4, NiFe2O4, CoMn2O4, and the like, and a combination thereof. Examples of semiconductor compound are the Group III-VI semiconductor compound, the Group II-VI semiconductor compound, the Group III-V semiconductor compound, the Group III-VI semiconductor compound, the Group I-III-VI semiconductor compound, the Group IV-VI semiconductor compound, or a combination thereof. For example, the semiconductor compound may include CdS, CdSe, CdTe, ZnS, ZnSe, ZnTe, ZnSeS, ZnTeS, GaAs, GaP, GaS, GaSe, AgGaS, AgGaS2, GaSb, HgS, HgSe, HgTe, InAs, InP, InGaP, InSb, AlAs, AlP, AlSb, or a combination thereof.

The element included in a multi-element compound, such as the binary compound and the tertiary compound, may be present in a particle in a uniform concentration or in an uneven concentration. In other words, the formula represents the type of element included in the compound, and the element ratios of the compounds may be different.

The quantum dots may have a full width of half maximum (FWHM) of about 45 nm or less, particularly about 40 nm or less, or particularly about 30 nm or less, and may improve color purity or color reproduction within the above range. In addition, because light emitted through the quantum dots are emitted in all directions, the light viewing angle may be improved.

In addition, the shape of the quantum dot may be spherical, pyramidal, multi-armed, or cubic and the quantum dot may be a nanoparticle, nanotube, nanowire, nanofiber, nanoplate particle, or the like.

Because the energy band gap is adjustable by controlling the size of the quantum dot or controlling the element ratio in the quantum dot compound, light of various wavelengths may be obtained from the quantum dot emission layer. Therefore, by using the quantum dots (quantum dots of different sizes or with different element ratios in the quantum dot compound) described above, a light-emitting diode emitting light of various wavelengths may be implemented. For example, controlling the size of the quantum dot or the element ratio of the quantum dot compound may result in emission of light selected from red, green, and/or blue light. In addition, the quantum dots may be configured to emit white light by a combination of light of various colors.

According to some embodiments, the third emission layer 220c may include an organic emission material. For example, the third emission layer 220c may not include quantum points and may only include organic materials. According to some embodiments, the third emission layer 220c including an organic emission material may be referred to as an organic emission layer. For example, the third emission layer 220c may include an organic material including a fluorescent or phosphorus material emitting red, green, blue, or white light. The third emission layer 220c described above may include an organic emission layer including a low molecular-weight organic material or a high molecular-weight organic material. For example, the third emission layer 220c, as an organic emission layer, may include copper phthalocyanine, tris-8-hydroxyquinoline aluminum, PPV (poly-phenylenevinylene)-based material, or polyfluorene-based material.

The first-1 functional layer 215a may be arranged in the first opening 120OP1 of the pixel defining layer 120. The first-1 functional layer 215a may be located on the first lower electrode 210a. The first-2 functional layer 215b may be arranged in the second opening 120OP2 of the pixel defining layer 120. The first-2 functional layer 215b may be located on the second lower electrode 210b. The first-3 functional layer 215c may be arranged in the third opening 120OP3 of the pixel defining layer 120. The first-3 functional layer 215c may be located on the third lower electrode 210c.

The level of an upper surface 215au of the first-1 functional layer 215a may be higher in the edge portion of the first-1 functional layer 215a than in the central portion of the first-1 functional layer 215a. Likewise, the level of an upper surface 215bu of the first-2 functional layer 215b may be higher in the edge portion of the first-2 functional layer 215b than in the central portion of the first-2 functional layer 215b. In contrast, the upper surface 215cu of the first-3 functional layer 215c may be substantially flat. Thus, the level of an upper surface 215cu of the first-3 functional layer 215c may be substantially the same in the central portion of the first-3 functional layer 215c and the edge portion of the first-3 functional layer 215c.

The first-1 functional layer 215a and the first-2 functional layer 215b may be formed by an inkjet printing process and the first-3 functional layer 215c may be formed by a vapor deposition process. The first-1 functional layer 215a and the first-2 functional layer 215b are formed in the same process and thus may have similar shapes. For example, as shown in FIG. 5, the level of each of the upper surface 215au of the first-1 functional layer 215a and the upper surface 215bu of the first-2 functional layer 215b may be lower in the central portions thereof than in the edge portions thereof, thereby forming a concave shape. In contrast, because the first-3 functional layer 215c is formed by a different process from that of the first-1 functional layer 215a and the first-2 functional layer 215b, the first-3 functional layer 215c may have a different shape from those of the first-1 functional layer 215a and the first-2 functional layer 215b. For example, as shown in FIG. 5, the upper surface 215cu of the first-3 functional layer 215c may be substantially flat unlike the upper surface 215au of the first-1 functional layer 215a and the upper surface 215bu of the first-2 functional layer 215b.

The second-1 functional layer 225a may be arranged in the first opening 120OP1 of the pixel defining layer 120. The second-1 functional layer 225a may be located on the first emission layer 220a. The second-2 functional layer 225b may be arranged in the second opening 120OP2 of the pixel defining layer 120. The second-2 functional layer 215b may be located on the second emission layer 220b. The second-3 functional layer 225c may be arranged in the third opening 120OP3 of the pixel defining layer 120. The second-3 functional layer 225c may be located on the third emission layer 220c.

The second-1 functional layer 225a, the second-2 functional layer 225b, and the second-3 functional layer 225c may be formed by the vapor deposition process. Because the upper surface 225au of the second-1 functional layer 225a, the upper surface 225bu of the second-2 functional layer 225b, and the upper surface 225cu of the second-3 functional layer 225c are formed by the same process, the shapes thereof may be substantially similar. For example, the upper surface 225au of the second-1 functional layer 225a, the upper surface 225bu of the second-2 functional layer 225b, and the upper surface 225cu of the second-3 functional layer 225c may be substantially flat.

According to some embodiments, the first-1 functional layer 215a, the first-2 functional layer 215b, and the first-3 functional layer 215c have the same function and the second-1 functional layer 225a, the second-2 functional layer 225b, and the second-3 functional layer 225c may have the same function. For example, the first-1 functional layer 215a, the first-2 functional layer 215b, and the first-3 functional layer 215c may each be a hole transport area, and the second-1 functional layer 225a, the second-2 functional layer 225b, and the second-3 functional layer 225c may each be an electron transport area. As another example, the first-1 functional layer 215a, the first-2 functional layer 215b, and the first-3 functional layer 215c may each be an electron transport area, and the second-1 functional layer 225a, the second-2 functional layer 225b, and the second-3 functional layer 225c may each be a hole transport area.

According to some embodiments, the first-1 functional layer 215a and the first-2 functional layer 215b included in the first light-emitting diode LED1 and the second light-emitting diode LED2 which are quantum dot light-emitting diodes may have different functions from that of the first-3 functional layer 215c included in the third light-emitting diode LED3 which is an organic light-emitting diode. In this case, the second-1 functional layer 225a and the second-2 functional layer 225b included in the first light-emitting diode LED1 and the second light-emitting diode LED2 which are quantum dot light-emitting diodes may have different functions from that of the second-3 functional layer 225c included in the third light-emitting diode LED3 which is an organic light-emitting diode. For example, the first-1 functional layer 215a and the first-2 functional layer 215b may be a hole transport area and the first-3 functional layer 215c may be an electron transport area. In this case, the second-1 functional layer 225a and the second-2 functional layer 225b may be an electron transport area and the second-3 functional layer 225c may be a hole transport area. In another example, the first-1 functional layer 215a and the first-2 functional layer 215b may be an electron transport area and the first-3 functional layer 215c may be a hole transport area. In this case, the second-1 functional layer 225a and the second-2 functional layer 225b may be a hole transport area and the second-3 functional layer 225c may be an electron transport area.

The electron transport area described above may include at least an electron transport layer (ETL) and further include an electron injection layer, a hole blocking layer, or a combination thereof. The hole transport area described above may include at least a hole transport layer (HTL) and further include a hole injection layer, an electron blocking layer, or a combination thereof.

According to some embodiments, the first-1 functional layer 215a and the second-1 functional layer 225a included in the first light-emitting diode LED1 which is a quantum dot light-emitting diode may be an inorganic functional layer including an inorganic material. According to some embodiments, the first-2 functional layer 215b and the second-2 functional layer 225b included in the second light-emitting diode LED2 which is a quantum dot light-emitting diode may be an inorganic functional layer including an inorganic material. The first-1 functional layer 215a and the first-2 functional layer 215b may be referred to as a first inorganic functional layer, and the second-1 functional layer 225a and the second-2 functional layer 225b may be referred to as a second inorganic functional layer.

The inorganic functional layer may include an inorganic HTL or an inorganic ETL. For example, when the first-1 functional layer 215a and the first-2 functional layer 215b include an inorganic HTL, the second-1 functional layer 225a and the second-2 functional layer 225b may include an inorganic ETL. In another example, when the first-1 functional layer 215a and the first-2 functional layer 215b include an inorganic ETL, the second-1 functional layer 225a and the second-2 functional layer 225b may include an inorganic HTL.

The inorganic HTL may include an inorganic oxide. For example, the inorganic HTL may include at least one of molybdenum oxide (MoOₓ), vanadium oxide (V₂O₅), hydrogen molybdenum bronze (HₓMoO₃), or hydrogen vanadium bronze (HₓV₂O₅). According to some embodiments, the inorganic HTL may include inorganic oxide and an organic material. For example, the inorganic HTL may include inorganic oxide and further include organic compounds such as tetra ([1,1′-biphenyl]-4-yl)-[1,1′: 4′, 1″-terphenyl]-4,4″-diamine (TaTm), 1,1-Bis[(di-4-tolylamino) phenyl]cyclohexane (TAPC), or 1,3-Bis (N-carbazolyl) benzene (mCP).

The inorganic ETL may at least include inorganic oxide. For example, the inorganic ETL may include inorganic oxide including at least one of TiO₂, ZnO, zinc magnesium oxide (ZnMgO), or tin oxide (SnOₓ). According to some embodiments, the inorganic ETL may further include Cs, Al, or a combination thereof. According to some embodiments, the inorganic ETL may further include organic material. For example, the inorganic ETL may include an organic compound including inorganic oxide and nitrogen. For example, the inorganic ETL may include inorganic oxide and an organic compound such as diphenyl-bis[4-(pyridin-3-yl)phenyl]silane (DPPS), 1,3,5-tri(m-pyrid-3-yl-phenyl)benzene (TmPyPB), or bis[2-(4,6-difluorophenyl)pyridinato-C2,N](picolinato)iridium (Flrpic).

According to some embodiments, the first-3 functional layer 215c and the second-3 functional layer 225c included in the third light-emitting diode LED3 which is an organic light-emitting diode may be an organic functional layer including an organic material. The first-3 functional layer 215c may be referred to as a first organic functional layer and the second-3 functional layer 225c may be referred to as a second organic functional layer. The organic functional layer may include an organic HTL or an organic ETL. For example, when the first-3 functional layer 215c includes an organic HTL, the second-3 functional layer 225c may include an organic ETL. For example, when the first-3 functional layer 215c includes an organic ETL, the second-3 functional layer 225c may include an organic HTL.

The organic HTL may include an organic material. For example, the organic HTL may include carbazole-based derivatives such as N-phenylcarbazole, polyvinylcarbazole, etc., fluorene-based derivatives, triphenylamine-based derivatives such as TPD(N,N′-bis(3-methylphenyl)-N, N′-diphenyl-[1,1-biphenyl]-4,4′-diamine), TCTA(4,4′,4″-tris (Ncarbazolyl) triphenylamine), etc., TFB (poly[(9,9-dioctylfluorenyl-2,7-diyl)-co-(4,4′-(N-(4-sec-butylphenyl)diphenylamine)]), PFO-TPA (poly(fluorine-co-triphenylamine)), TPD-BCB, TCz II, PS-TPD-TFV, Tri-TFV-TCTA, NPB (N,N′-di(1-naphthyl)-N,N′-diphenylbenzidine), TAPC(4,4′-Cyclohexylidene bis[N, N-bis(4-methylphenyl)benzenamine]), or HMTPD(4,4′-Bis[N,N′-(3-tolyl)amino]-3,3′-dimethylbiphenyl).

The organic ETL may include an organic material. For example, the organic electron transport layer may include tris (8-hydroxyquinolinato) aluminum (Alq3), 1,3,5-tri[(3-pyridyl)-phen-3-yl]benzene, 2,4,6-tris(3′-(pyridin-3-yl) biphenyl-3-yl)-1,3,5-triazine, 2-(4-(N-phenylbenzoimidazolyl-1-ylphenyl)-9,10-dinaphthylanthracene, 1,3,5-tri(1-phenyl-1H-benzo[d]imidazol-2-yl)phenyl (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-n1,08)-(1,1′-biphenyl-4-olato) aluminum (BAlq), berylliumbis (benzoquinolin-10-olate) (Bebq2), 9,10-di (naphthalene-2-yl) anthracene (ADN), 9,9-di (4,4′-bis(3,6-di-tert-butylcarbazole)-phenyl)-9H-fluorene (TBCPF), BA, 2,7-bis (diphenylphosphoryl)-9,9 (SPPO13), 9-(3-(9H-carbazol-9-yl)phenyl)-3-(diphenylphosphoryl)-9H-carbazole (mCPP01), 2,2′,2″-(1,3,5-benzinetriyl)-tris (1-phenyl-1-H-benzimidazole) (TPBi), m-PhOTPBi, poly[9,9-bis(6′-(diethanolamino) hexyl)-fluorene] (PFN-OH), or a mixture thereof, but embodiments are not limited thereto.

The upper electrode 230 may include the first upper electrode 230a of the first light-emitting diode LED1, the second upper electrode 230b of the second light-emitting diode LED2, and the third upper electrode 230c of the third light-emitting diode LED3. The first upper electrode 230a, the second upper electrode 230b, and the third upper electrode 230c may be integrally provided as a single upper electrode 230. The upper electrode 230 may be integrally provided across the entire surface of the substrate 100 to cover the second-1 functional layer 225a, the second-2 functional layer 225b, and the second-3 functional layer 225c.

The upper electrode 230 may include a metal, an alloy, an electrically conductive compound, or a combination thereof having a low work function. The upper electrode 230 may include, for example, lithium (Li), Ag, Mg, Al, aluminum-lithium (Al—Li), Ca, magnesium-indium (Mg—In), magnesium-silver (Mg—Ag), ytterbium (Yb), silver-ytterbium (Ag—Yb), ITO, IZO, or a combination thereof. The upper electrode 230 may be a transmissive electrode, a transflective electrode, or a reflective electrode. The upper electrode 230 may have single-layer structure including a single layer or a multi-layer structure including a plurality of layers.

The display device 1 may have a structure including both the quantum dot light-emitting diode and the organic light-emitting diode. The quantum dot light-emitting diode has a low material cost and excellent color coordinates. The organic light-emitting diode has a longer lifespan compared to that of the quantum dot light-emitting diode. Because a quantum dot light-emitting diode is used in the first light-emitting diode LED1 and the second light-emitting diode LED2 and an organic light-emitting diode is used in the third light-emitting diode LED3 of the display device 1 according to some embodiments, the color purity and color reproduction is improved, thereby implementing excellent luminescent characteristics and a long lifespan. The disclosure is not limited to the first light-emitting diode LED1 and the second light-emitting diode LED2 including the quantum dot light-emitting diode and the third light-emitting diode LED3 including the organic light-emitting diode. Thus, the first light-emitting diode LED1 or the second light-emitting diode LED2 may include an organic light-emitting diode and the third light-emitting diode LED3 may include a quantum dot light-emitting diode.

According to some embodiments, the thin-film encapsulation layer TFE may be located on the first light-emitting diode LED1, the second light-emitting diode LED2, and the third light-emitting diode LED3. The thin-film encapsulation layer TFE may include at least one inorganic encapsulation layer and at least one organic encapsulation layer. According to some embodiments, as shown in FIG. 5, the thin-film encapsulation layer TFE may include a first inorganic encapsulation layer 510 on the display element layer DEL, an organic encapsulation layer 520 on the first inorganic encapsulation layer 510, and a second inorganic encapsulation layer 530 on the organic encapsulation layer 520.

The first inorganic encapsulation layer 510 and the second inorganic encapsulation layer 530 may include, for example, an inorganic insulating material such as Al₂O₃, TiO₂, Ta₂O₅, HfO₂, ZnO, SiOₓ, SiNₓ, or SiON. The organic encapsulation layer 520 may include, for example, a polymer-based material. Examples of the polymer-based material may include an acrylic resin, an epoxy resin, polyimide, and polyethylene. According to some embodiments, the organic encapsulation layer may include acrylate.

FIG. 5 illustrates that the light-emitting diodes are sealed by the thin-film encapsulation layer TFE, but embodiments are not limited thereto, and, as illustrated in FIG. 3B, the light-emitting diodes may be sealed by the sealing member 300 and the sealing substrate 400 according to some embodiments.

FIGS. 6 to 13 are each a schematic cross-sectional view of a manufacturing process of the display device according to some embodiments. FIGS. 6 to 13 are cross-sectional views of the display device taken along the line I-I′ of FIG. 4 according to each manufacturing step of the display device.

Referring to FIG. 6, the pixel circuit layer PCL is formed on the substrate 100 and a first lower electrode 210a, the second lower electrode 210b, and the third lower electrode 210c may be formed on the pixel circuit layer PCL.

The pixel circuit layer PCL may include the first transistor TR1, the second transistor TR2, and the third transistor TR3. The first lower electrode 210a, the second lower electrode 210b, and the third lower electrode 210c may be apart from each other on the planarization layer 119. The first lower electrode 210a may correspond to the first pixel PX1 (FIG. 4), the second lower electrode 210b may correspond to the second pixel PX2 (FIG. 4), and the third lower electrode 210c may correspond to the third pixel PX3 (FIG. 4). The first lower electrode 210a may be electrically connected to the first transistor TR1, the second lower electrode 210b may be electrically connected to the second transistor TR2, and the third lower electrode 210c may be electrically connected to the third transistor TR3.

The first lower electrode 210a, the second lower electrode 210b, and the third lower electrode 210c may be (semi-) transmissive electrodes or reflective electrodes. The first lower electrode 210a, the second lower electrode 210b, and the third lower electrode 210c may each include a reflective layer including Ag, Mg, Al, Pt, Pd, Au, Ni, Nd, Ir, Cr, and compounds thereof and a transparent or semi-transparent electrode layer formed on the reflective layer. The transparent or semi-transparent electrode layer may include at least one selected of indium tin oxide (ITO), indium zinc oxide (IZO), zinc oxide (ZnO), indium oxide (In₂O₃), indium gallium oxide (IGO), or aluminum zinc oxide (AZO). According to some embodiments, each of the first lower electrode 210a, the second lower electrode 210b, and the third lower electrode 210c may include ITO/Ag/ITO.

Next, the pixel defining layer 120 may be formed on the pixel circuit layer PCL. The pixel defining layer 120 may cover edges of the first lower electrode 210a, the second lower electrode 210b, and the third lower electrode 210c and may include the first opening 120OP1 exposing the central portion of the first lower electrode 210a, the second opening 120OP2 exposing the central portion of the second lower electrode 210b, and the third opening 120OP3 exposing the central portion of the third lower electrode 210c.

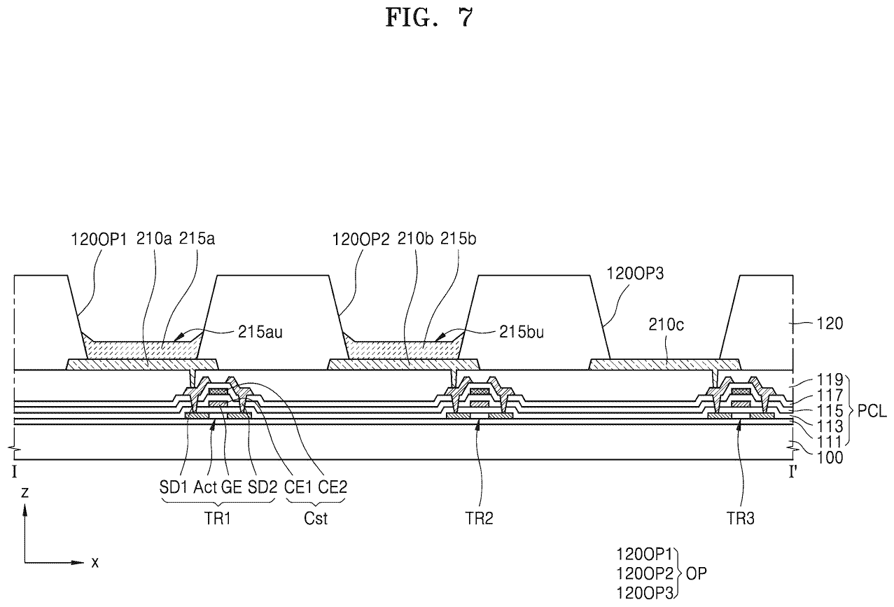

Next, referring to FIG. 7, the first-1 functional layer 215a and the first-2 functional layer 215b may be respectively located on the first lower electrode 210a and the second lower electrode 210b. The first-1 functional layer 215a may be formed in the first opening 120OP1 of the pixel defining layer 120 and the first-2 functional layer 215b may be formed in the second opening 120OP2 of the pixel defining layer 120.

The first-1 functional layer 215a and the first-2 functional layer 215b may be formed through the inkjet printing process. Because the first-1 functional layer 215a and the first-2 functional layer 215b are formed through the inkjet printing process, liquid may flow to the edges due to the difference in evaporation speed of liquid included in each functional layer, thereby causing the upper surface 215au of the first-1 functional layer 215a and the upper surface 215bu of the first-2 functional layer 215b to be concave in the central portions thereof. That is, the level of the upper surface 215au of the first-1 functional layer 215a may be higher in the edge portion of the first-1 functional layer 215a than in the central portion of the first-1 functional layer 215a. Likewise, the level of the upper surface 215bu of the first-2 functional layer 215b may be higher in the edge portion of the first-2 functional layer 215b than in the central portion of the first-2 functional layer 215b.

The first-1 functional layer 215a and the first-2 functional layer 215b may include an inorganic material.

For example, when the first-1 functional layer 215a and the first-2 functional layer 215b include an inorganic HTL, the first-1 functional layer 215a and the first-2 functional layer 215b may include at least one of MoOₓ, V₂O₅, HₓMoO₃, or HₓV₂O₅.

For example, when the first-1 functional layer 215a and the first-2 functional layer 215b include an inorganic ETL, the first-1 functional layer 215a and the first-2 functional layer 215b may include an inorganic oxide including at least one of TiO₂), ZnO, ZnMgO, or SnOₓ. According to some embodiments, when the first-1 functional layer 215a and the first-2 functional layer 215b include an inorganic ETL, the first-1 functional layer 215a and the first-2 functional layer 215b may further include Cs, Al, or a combination thereof.

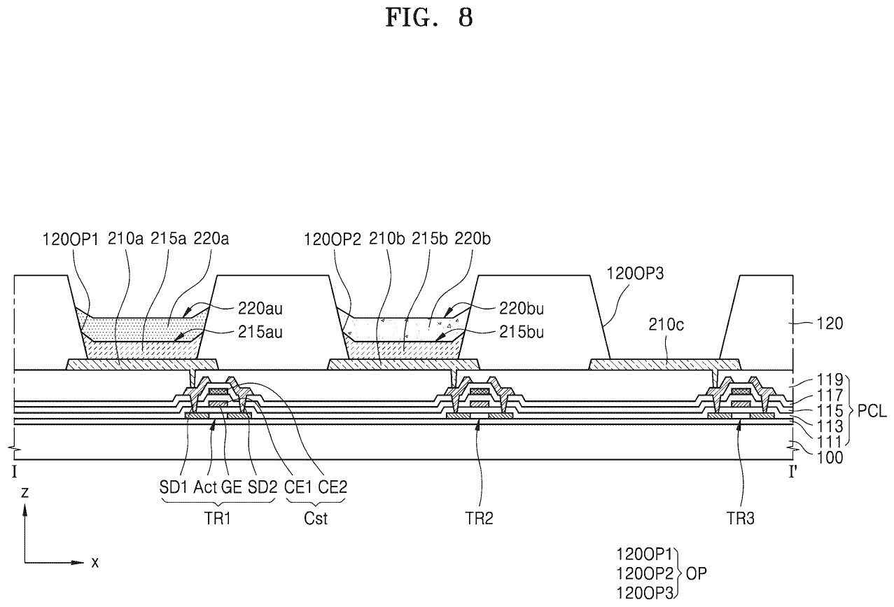

Next, referring to FIG. 8, the first emission layer 220a and the second emission layer 220b may be respectively located on the first-1 functional layer 215a and the first-2 functional layer 215b. The first emission layer 220a may be formed in the first opening 120OP1 of the pixel defining layer 120 and the second emission layer 220b may be formed in the second opening 120OP2 of the pixel defining layer 120.

The first emission layer 220a and the second emission layer 220b may be formed through the inkjet printing process. Because the first emission layer 220a and the second emission layer 220b are formed through the inkjet printing process, liquid may flow to the edges due to the difference in evaporation speed of liquid included in each functional layer, thereby causing the upper surface 220au of the first emission layer 220a and the upper surface 220bu of the second emission layer 220b to be concave in the central portions thereof. That is, the level of the upper surface 220au of the first emission layer 220a may be higher in the edge portion of the first emission layer 220a than in the central portion of the first emission layer 220a. Likewise, the level of an upper surface 220bu of the second emission layer 220b may be higher in the edge portion of the second emission layer 220b than in the central portion of the second emission layer 220b.

The first emission layer 220a and the second emission layer 220b may include an inorganic emission material. For example, the first emission layer 220a and the second emission layer 220b may include quantum dots. According to some embodiments, the first emission layer 220a and the second emission layer 220b including quantum dots may be referred to as a first quantum dot emission layer and the second quantum dot emission layer, respectively. The quantum dots included in the first emission layer 220a and the second emission layer 220b may act as dopants, and the emission layers may further include hosts and/or delayed fluorescent materials.

After forming the first emission layer 220a and the second emission layer 220b, which are quantum dot emission layers, by the inkjet printing process, a structure wherein the pixel circuit layer PCL, the pixel defining layer 120, the first-1 functional layer 215a, the first-2 functional layer 215b, the first emission layer 220a, and the second emission layer 220b are formed on the substrate 100 may be moved into deposition equipment.

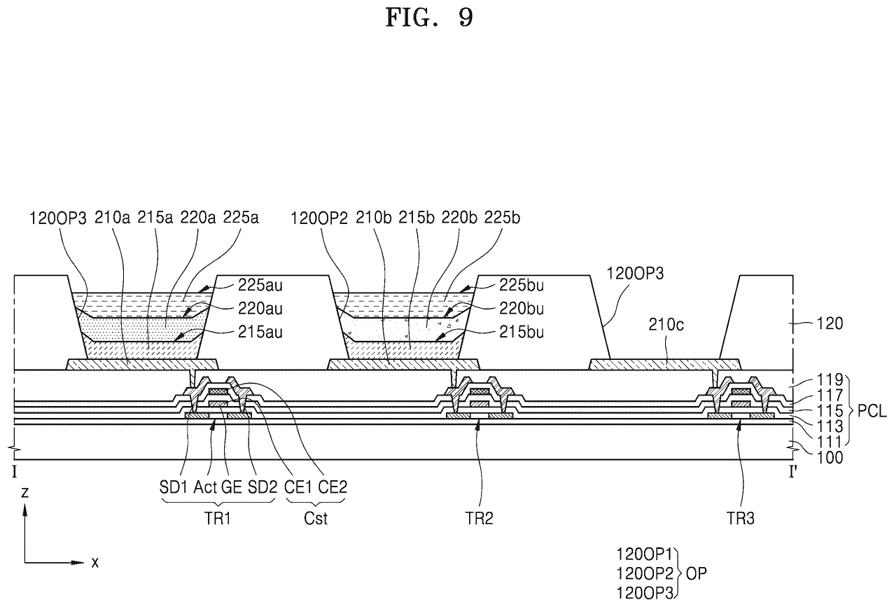

Next, referring to FIG. 9, the second-1 functional layer 225a and the second-2 functional layer 225b may be respectively located on the first emission layer 220a and the second emission layer 220b. The second-1 functional layer 225a may be formed in the first opening 120OP1 of the pixel defining layer 120 and the second-2 functional layer 225b may be formed in the second opening 120OP2 of the pixel defining layer 120.

The second-1 functional layer 225a and the second-2 functional layer 225b may include an inorganic material.

For example, when the first-1 functional layer 215a and the first-2 functional layer 215b include an inorganic HTL, the second-1 functional layer 225a and the second-2 functional layer 225b may include an inorganic ETL. For example, when the first-1 functional layer 215a and the first-2 functional layer 215b includes at least one of MoOₓ, V₂O₅, HₓMoO₃, or HₓV₂O₅, the second-1 functional layer 225a and the second-2 functional layer 225b may include an inorganic oxide including at least one of TiO₂, ZnO, ZnMgO, or SnOₓ. According to some embodiments, when the second-1 functional layer 225a and the second-2 functional layer 225b include an inorganic ETL, the second-1 functional layer 225a and the second-2 functional layer 225b may further include Cs, Al, or a combination thereof. According to some embodiments, when the second-1 functional layer 225a and the second-2 functional layer 225b include an inorganic ETL, the second-1 functional layer 225a and the second-2 functional layer 225b may further include an organic compound such as diphenyl-bis[4-(pyridin-3-yl)phenyl]silane (DPPS), 1,3,5-tri (m-pyrid-3-yl-phenyl) benzene (TmPyPB), or bis[2-(4,6-difluorophenyl)pyridinato-C2,N](picolinato)iridium (Flrpic). The organic compound included in the second-1 functional layer 225a and the second-2 functional layer 225b may be deposited with the inorganic oxide through co-evaporation.

According to some embodiments, when the first-1 functional layer 215a and the first-2 functional layer 215b include an inorganic ETL, the second-1 functional layer 225a and the second-2 functional layer 225b may include an inorganic HTL. For example, when the first-1 functional layer 215a and the first-2 functional layer 215b include an inorganic oxide including at least one of TiO₂, ZnO, ZnMgO, or SnOₓ, the second-1 functional layer 225a and the second-2 functional layer 225b may include at least one of MoOₓ, V₂O₅, HₓMoO₃, or HₓV₂O₅. According to some embodiments, when the second-1 functional layer 225a and the second-2 functional layer 225b include an inorganic HTL, the inorganic HTL may include inorganic oxide and further include an organic compound such as tetra ([1,1′-biphenyl]-4-yl)-[1,1′:4′,1″-terphenyl]-4,4″-diamine (TaTm), 1,1-bis[(di-4-tolylamino)phenyl]cyclohexane (TAPC), or 1,3-Bis (N-carbazolyl) benzene (mCP). The organic compound included in the second-1 functional layer 225a and the second-2 functional layer 225b may be deposited with the inorganic oxide through co-evaporation.

The second-1 functional layer 225a and the second-2 functional layer 225b may be formed by the vapor deposition process. Unlike the disclosure, when the second-1 functional layer 225a and the second-2 functional layer 225b are formed by the inkjet printing process, due to an intermixing of the first emission layer 220a and the second emission layer 220b and the inorganic oxide included in the second-1 functional layer 225a and the second-2 functional layer 225b, the inflow of the quantum dots included in the first emission layer 220a and the second emission layer 220b to the second-1 functional layer 225a and the second-2 functional layer 225a may be increased. When the intermixing between the functional layer and the emission layer is increased, the efficiency and lifespan of the light-emitting diode may be decreased. In the embodiments of the disclosure, because the second-1 functional layer 225a and the second-2 functional layer 225b are formed by the vapor deposition process, the intermixing between the functional layer and the emission layer is decreased, thereby improving the stability of interfaces between the second-1 functional layer 225a and the first emission layer 220a and between the second-2 functional layer 225b and the second emission layer 220b.

Because the second-1 functional layer 225a and the second-2 functional layer 225b are formed by the vapor deposition process, the upper surface 225au of the second-1 functional layer 225a and the upper surface 225bu of the second-2 functional layer 225b may be substantially flat.

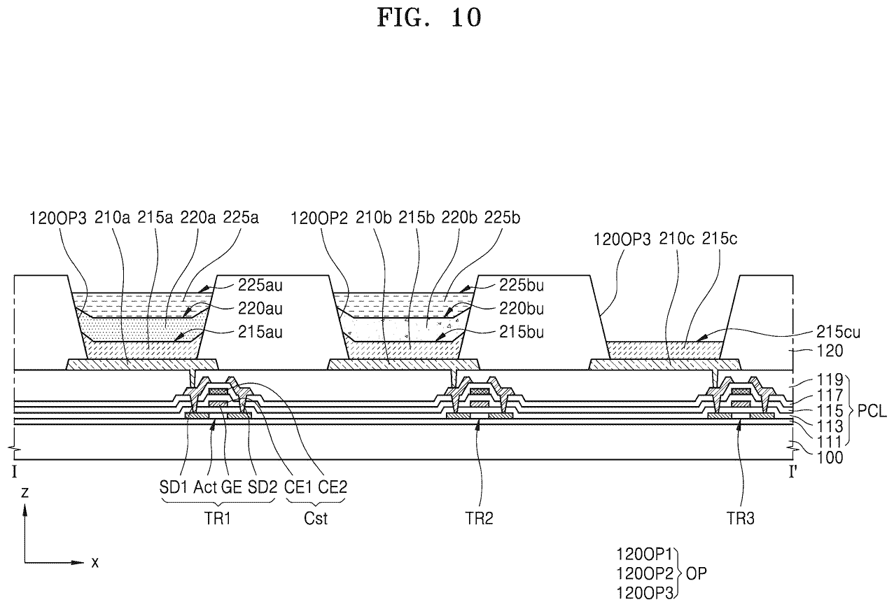

Next, referring to FIG. 10, the first-3 functional layer 215c may be formed on the third lower electrode 210c. The first-3 functional layer 215c may be arranged in the third opening 120OP3 of the pixel defining layer 120.

The first-3 functional layer 215c may be formed by the vapor deposition process. Because the first-3 functional layer 215c is formed by the vapor deposition process, the first-3 functional layer 215c may have a substantially flat shape unlike the upper surface 215au of the first-1 functional layer 215a and the upper surface 215bu of the first-2 functional layer 215b. Thus, the level of the upper surface 215cu of the first-3 functional layer 215c may be substantially the same in the central portion of the first-3 functional layer 215c and the edge portion of the first-3 functional layer 215c.

The first-3 functional layer 215c may include an organic material.

For example, when the first-3 functional layer 215c includes an organic HTL, the first-3 functional layer 215c may include a carbazole-based derivative such as N-phenylcarbazole and polyvinylcarbazole, a fluorene-based derivative, a triphenylamine-based derivative such as N,N′-bis(3-methylphenyl)-N,N′-diphenyl-[1,1-biphenyl]-4,4′-diamine (TPD) and 4,4′,4″-tris (Ncarbazolyl) triphenylamine (TCTA), N,N′-di (1-naphthyl)-N,N′-diphenylbenzidine (NPB), 4,4′-cyclohexylidene bis[N,N-bis(4-methylphenyl)benzenamine] (TAPC), 4,4′-bis[N,N′-(3-tolyl) amino]-3,3′-dimethylbiphenyl (HMTPD), or the like.

For example, when the first-3 functional layer 215c includes an organic ETL, the first-3 functional layer 215c may include tris (8-hydroxyquinolinato) aluminum (Alq3), 1,3,5-tri[(3-pyridyl)-phen-3-yl]benzene, 2,4,6-tris (3′-(pyridin-3-yl) biphenyl-3-yl)-1,3,5-triazine, 2-(4-(N-phenylbenzoimidazolyl-1-ylphenyl)-9, 10-dinaphthylanthracene, 1,3,5-tri (1-phenyl-1H-benzo[d]imidazol-2-yl) phenyl (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato) aluminum (BAlq), berylliumbis (benzoquinolin-10-olate (Bebq2), 9,10-di(naphthalene-2-yl) anthracene (ADN), or a mixture thereof.

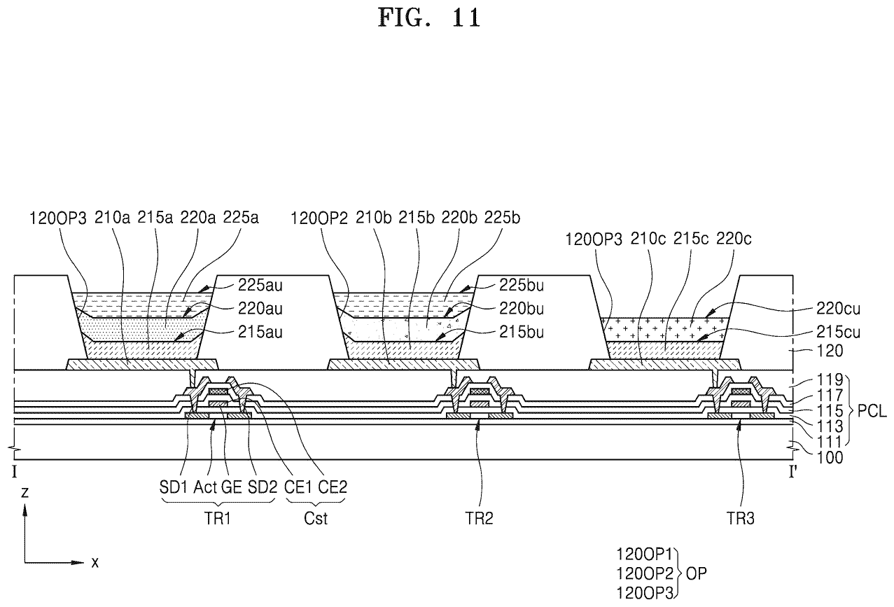

Referring to FIG. 11, the third emission layer 220c may be located on the first-3 functional layer 225c. The third emission layer 220c may be arranged in the third opening 120OP3 of the pixel defining layer 120.

The third emission layer 220c may be formed by the vapor deposition process. Because the third emission layer 220c is formed by the vapor deposition process, the third emission layer 220c may have a substantially flat shape unlike the upper surface 220au of the first emission layer 220a and the upper surface 220bu of the second emission layer 220b. Thus, the level of the upper surface 220cu of the third emission layer 220c may be substantially the same in the central portion of the third emission layer 220c and the edge portion of the third emission layer 220c.

The third emission layer 220c may include an organic emission material. For example, the third emission layer 220c may not include quantum points and may only include organic materials. According to some embodiments, the third emission layer 220c including an organic emission material may be referred to as an organic emission layer. For example, the third emission layer 220c may include an organic material including a fluorescent or phosphorus material emitting red, green, blue, or white light. The third emission layer 220c described above may include an organic emission layer including a low molecular-weight organic material or a high molecular-weight organic material. For example, the third emission layer 220c, as an organic emission layer, may include copper phthalocyanine, tris-8-hydroxyquinoline aluminum, PPV (poly-phenylenevinylene)-based material, or polyfluorene-based material.

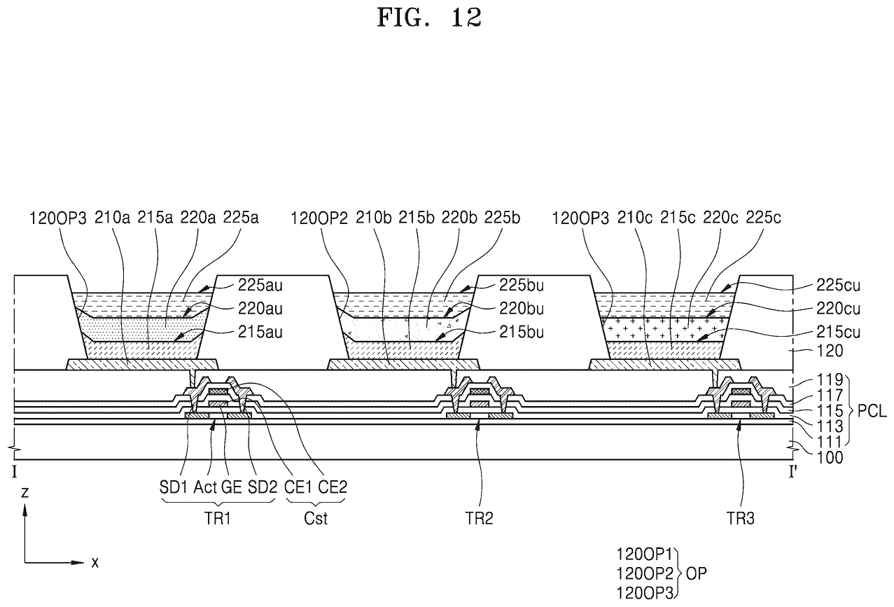

Referring to FIG. 12, the second-3 functional layer 225c may be located on the third emission layer 220c. The second-3 functional layer 225b may be arranged in the third opening 120OP3 of the pixel defining layer 120.

The second-3 functional layer 225c may include an organic material.

According to some embodiments, when the first-3 functional layer 215c includes an organic HTL, the second-3 functional layer 225c may include an organic ETL. For example, when the first-3 functional layer 215c includes a carbazole-based derivative such as N-phenylcarbazole and polyvinylcarbazole, a fluorene-based derivative, a triphenylamine derivative such as N,N′-bis(3-methylphenyl)-N,N′-diphenyl-[1,1-biphenyl]-4,4′-diamine (TPD) and 4,4′,4″-tris(Ncarbazolyl) triphenylamine (TCTA), N,N′-di (1-naphthyl)-N,N′-diphenylbenzidine (NPB), 4,4′-cyclohexylidene bis[N,N-bis(4-methylphenyl) benzenamine] (TAPC), 4,4′-Bis[N,N′-(3-tolyl) amino]-3,3′-dimethylbiphenyl (HMTPD), etc., the second-3 functional layer 225c may include tris (8-hydroxyquinolinato) aluminum (Alq3), 1,3,5-tri[(3-pyridyl)-phen-3-yl]benzene, 2,4,6-tris (3′-(pyridin-3-yl) biphenyl-3-yl)-1,3,5-triazine, 2-(4-(N-phenylbenzoimidazolyl-1-ylphenyl)-9,10-dinaphthylanthracene, 1,3,5-tri (1-phenyl-1H-benzo[d]imidazol-2-yl) phenyl (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-Biphenylyl)-5-(4-tert-butylphenyl)-1,3,4-oxadiazole (tBu-PBD), bis(2-methyl-8-quinolinolato-N1,O8)-(1,1′-Biphenyl-4-olato) aluminum (BAlq), berylliumbis (benzoquinolin-10-olate) (Bebq2), 9,10-di(naphthalene-2-yl) anthracene (ADN), or a mixture thereof.

In contrast, when the first-3 functional layer 215c includes an organic ETL, the second-3 functional layer 225c may include an organic HTL.

Because the second-3 functional layer 225c is formed by the vapor deposition process, the upper surface 225cu of the second-3 functional layer 225c may be substantially flat.

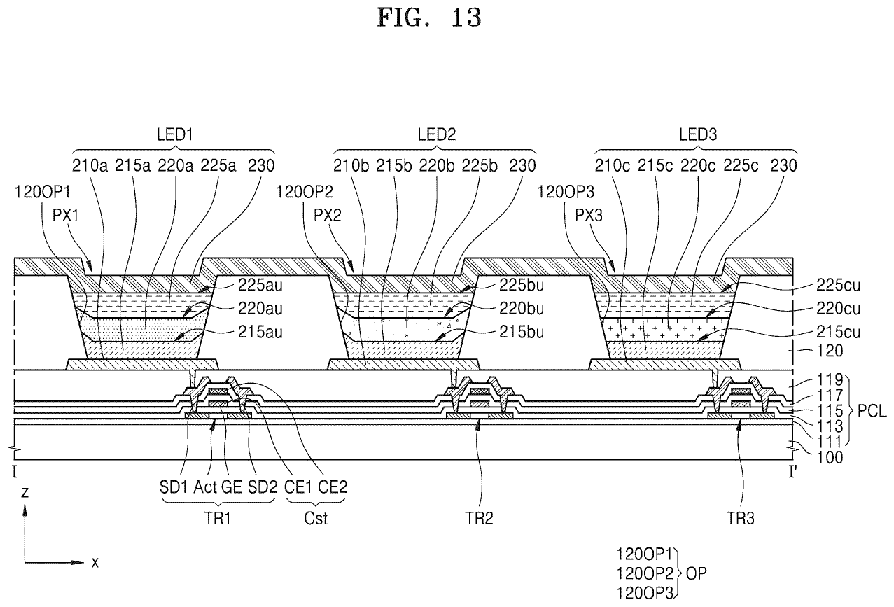

Referring to FIG. 13, the upper electrode 230 may be located on the second-1 functional layer 225a, the second-2 functional layer 225b, and the second-3 functional layer 225c. The upper electrode 230 may be integrally provided across the entire surface of the substrate 100.

The upper electrode 230 may include a metal, an alloy, an electrically conductive compound, or a combination thereof having a low work function. The upper electrode 230 may include, for example, lithium (Li), Ag, Mg, Al, aluminum-lithium (Al—Li), Ca, magnesium-indium (Mg—In ), magnesium-silver (Mg—Ag), ytterbium (Yb), silver-ytterbium (Ag—Yb), ITO, IZO, or a combination thereof. The upper electrode 230 may be a transmissive electrode, a transflective electrode, or a reflective electrode. The upper electrode 230 may have single-layer structure including a single layer or a multi-layer structure including a plurality of layers.

Next, referring to FIG. 5, according to some embodiments, the thin-film encapsulation layer TFE may further be formed on the upper electrode 230.

In the quantum dot light-emitting diode of the display device of the disclosure, for the interface stability between the functional layer and the quantum dot emission layer, the functional layers arranged over and below the quantum dot emission layer may be formed of inorganic materials. In addition, in the quantum dot light-emitting diode of the display device of the disclosure, for the interface stability between the functional layer and the organic emission layer, the functional layers arranged over and below the organic emission layer may be formed of organic materials.

In the display device of the disclosure, the first inorganic functional layer and the quantum dot emission layer are sequentially formed by the inkjet printing process, the second inorganic functional layer is formed by the vapor deposition process, and then the first organic functional layer, the organic emission layer, and the second organic functional layer are sequentially formed through the vapor deposition process, thereby preventing or reducing a frequent movement of equipment to increase process efficiency.

A display device according to some embodiments of the present disclosure may include the light-emitting diode including the quantum dot emission layer and the light-emitting diode including the organic emission layer, thereby improving luminous efficiency and lifespan.

In the display device according to the disclosure, the emission layer of the light-emitting diode including the quantum dot emission layer may be formed by the inkjet printing process and an inorganic common layer on the emission layer may be formed by the vapor deposition process, thereby improving the reliability of the display device.

However, the embodiments are only examples and do not limit the scope of embodiments according to the present disclosure.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and their equivalents.

What is claimed is:

1. A display device comprising:
a first light-emitting diode and a second light-emitting diode each on a substrate, the first light-emitting diode and the second light-emitting diode configured to emit light of different colors from each other,
wherein the first light-emitting diode comprises:
a first lower electrode;
a first inorganic functional layer on the first lower electrode and including an inorganic material;
a quantum dot emission layer on the first inorganic functional layer and including a quantum dot;
a second inorganic functional layer on the quantum dot emission layer and including an inorganic material; and
a first upper electrode on the second inorganic functional layer,
wherein the second light-emitting diode comprises:
a second lower electrode;
a first organic functional layer on the second lower electrode and including an organic material;
an organic emission layer on the first organic functional layer and comprising an organic material;
a second organic functional layer on the organic emission layer and comprising an organic material; and
a second upper electrode on the second organic functional layer,
wherein a level of an upper surface of the first inorganic functional layer is higher in an edge portion of the first inorganic functional layer than in a central portion of the first inorganic functional layer, and
a level of an upper surface of the first organic functional layer is equal in a central portion and an edge portion of the first organic functional layer.

2. The display device of claim 1, wherein a level of an upper surface of the quantum dot emission layer is higher in an edge portion of the quantum dot emission layer than in a central portion of the quantum dot emission layer, and
a level of an upper surface of the organic emission layer is equal in a central portion and an edge portion of the organic emission layer.

3. The display device of claim 1, wherein a level of an upper surface of the second inorganic functional layer is equal in a central portion and an edge portion of the second inorganic functional layer, and
a level of an upper surface of the second organic functional layer is equal in a central portion and an edge portion of the second organic functional layer.

4. The display device of claim 1, wherein the first inorganic functional layer comprises at least one of molybdenum oxide, vanadium oxide, hydrogen molybdenum bronze, or hydrogen vanadium bronze.

5. The display device of claim 4, wherein the second inorganic functional layer comprises at least one of titanium oxide, zinc oxide, zinc magnesium oxide, or tin oxide.

6. The display device of claim 1, wherein the first inorganic functional layer comprises at least one of titanium oxide, zinc oxide, zinc magnesium oxide, or tin oxide.

7. The display device of claim 6, wherein the second inorganic functional layer comprises at least one of molybdenum oxide, vanadium oxide, hydrogen molybdenum bronze, or hydrogen vanadium bronze.

8. The display device of claim 1, further comprising a pixel defining layer on the substrate, covering an edge of each of the first lower electrode and the second lower electrode, and comprising a first opening exposing a central portion of the first lower electrode and a second opening exposing a central portion of the second lower electrode.

9. The display device of claim 8, wherein the first inorganic functional layer, the quantum dot emission layer, and the second inorganic functional layer are arranged in the first opening of the pixel defining layer, and
the first organic functional layer, the organic emission layer, and the second organic functional layer are arranged in the second opening of the pixel defining layer.

10. The display device of claim 1, wherein the first upper electrode and the second upper electrode are integrally provided.

11. A method of manufacturing a display device, the method comprising:
forming a first lower electrode and a second lower electrode on a substrate;
performing an inkjet printing process on the first lower electrode to form a first inorganic functional layer comprising an inorganic material;
performing an inkjet printing process on the first functional layer to form a quantum dot emission layer comprising a quantum dot;
performing a vapor deposition process on the quantum dot emission layer to form a second inorganic functional layer;
forming a first organic functional layer comprising an organic material on the second lower electrode;
forming an organic emission layer on the first organic functional layer;
forming a second organic functional layer comprising an organic material on the organic emission layer; and
forming an upper electrode on the second inorganic functional layer and the second organic functional layer.

12. The method of claim 11, wherein the first organic functional layer is formed by the vapor deposition process.

13. The method of claim 11, wherein the forming of the first organic functional layer is performed after the forming of the second inorganic functional layer.

14. The method of claim 11, wherein each of the organic emission layer and the second organic functional layer is formed by the vapor deposition process.

15. The method of claim 11, wherein the first inorganic functional layer comprises at least one of molybdenum oxide, vanadium oxide, hydrogen molybdenum bronze, or hydrogen vanadium bronze.

16. The method of claim 15, wherein the second inorganic functional layer comprises at least one of titanium oxide, zinc oxide, zinc magnesium oxide, or tin oxide.

17. The method of claim 11, wherein the first inorganic functional layer comprises at least one of titanium oxide, zinc oxide, zinc magnesium oxide, or tin oxide.

18. The method of claim 17, wherein the second inorganic functional layer comprises at least one of molybdenum oxide, vanadium oxide, hydrogen molybdenum bronze, or hydrogen vanadium bronze.

19. The method of claim 11, further comprising forming a pixel defining layer on the substrate, covering an edge of each of the first lower electrode and the second lower electrode, and comprising a first opening exposing a central portion of the first lower electrode and a second opening exposing a central portion of the second lower electrode.

20. The method of claim 19, wherein the first inorganic functional layer, the quantum dot emission layer, and the second inorganic functional layer are arranged in the first opening of the pixel defining layer, and
the first organic functional layer, the organic emission layer, and the second organic functional layer are arranged in the second opening of the pixel defining layer.
